(19) United States
(12) Patent Application Publication
(10) Pub. No.: US 2025/0015523 A1
(43) Pub. Date: Jan. 9, 2025

(54) WIRING UNIT

(71) Applicant: NIPPON MEKTRON, LTD., Tokyo (JP)

(72) Inventors: Tasuku ONO, Tokyo (JP); Tomoki KANAYAMA, Tokyo (JP)

(73) Assignee: NIPPON MEKTRON, LTD., Tokyo (JP)

(21) Appl. No.: 18/736,466

(22) Filed: Jun. 6, 2024

(30) Foreign Application Priority Data
Jul. 3, 2023 (JP) 2023-109168

(51) Int. Cl. H01R 12/77; H01R 13/422; H01R 13/50; H01R 13/52

(52) U.S. Cl. CPC H01R 12/77; H01R 13/422; H01R 13/501; H01R 13/5205; H01R 13/5213

(57) ABSTRACT

Provided is a wiring unit including a flexible printed circuit board having a first surface and a second surface, a connector, a holding member, and a cover, the flexible printed circuit board has wirings; the connector has a housing case and terminals, the connector is connected to the first surface at one end side in a longitudinal direction of the flexible printed circuit board, the terminals are connected to the wirings on the other end side in the longitudinal direction from the housing case; the holding member is provided to hold the flexible printed circuit board on the second surface; the holding member has a recess on the other end side in the longitudinal direction from the terminals, and the cover has a pressing portion to press and make a part of the flexible printed circuit board enter the recess.

### CROSS-REFERENCE TO RELATED APPLICATION

This application claims priority from Japanese Patent Application No. 2023-109168 filed with the Japan Patent Office on Jul. 3, 2023, the entire content of which is hereby incorporated by reference.

### BACKGROUND

### 1. Technical Field

The present disclosure relates to a wiring unit having a flexible printed circuit board.

### 2. Related Art

A flexible printed circuit board (hereinafter may be referred to as “FPC”) is often used with a connector connected thereto in order to connect to other wiring or devices. When used for outdoor equipment or in-vehicle applications, there are known techniques such as applying a resin material to the connecting portion to make it waterproof, or using a waterproof connector, in order to prevent dew condensation water and the like from entering a connecting portion with a connector through the FPC (JP-A-2013-054940). However, these methods have a problem of high costs.

Further, there is also known a technique for suppressing entry of the dew condensation water and the like into the connecting portion of the connector by devising a method for arranging the connector and the FPC (JP-A-2022-071455). However, there is a problem that such a technique cannot be employed if there is a restriction on a space for arranging the FPC or the like.

### SUMMARY

A wiring unit according to an embodiment of the present disclosure includes a flexible printed circuit board, a connector, a holding member, and a cover, in which the flexible printed circuit board has a first surface and a second surface opposite to the first surface, and has a plurality of wirings; the connector has a housing case and a plurality of terminals, the connector is connected to the first surface of the flexible printed circuit board at one end side in a longitudinal direction of the flexible printed circuit board, the plurality of terminals are provided to protrude from an inside of the housing case to an outside and to be respectively connected to the plurality of wirings on the other end side in the longitudinal direction from the housing case; the holding member is provided to hold the flexible printed circuit board on the second surface of the flexible printed circuit board; the cover is provided to sandwich the connector between the cover and the holding member in a thickness direction of the flexible printed circuit board; the holding member has a recess, and the recess is located on the other end side in the longitudinal direction from the plurality of terminals, and is provided to be recessed toward a side opposite to the connector in the thickness direction, and the cover has a pressing portion, and the pressing portion is provided to press and make a part of the flexible printed circuit board enter the recess.

### BRIEF DESCRIPTION OF THE DRAWINGS

FIGS. 1A and 1B are parts of an external view of a wiring unit according to an embodiment of the present disclosure;

FIG. 2 is a front view of a cover according to the embodiment of the present disclosure;

FIGS. 3A and 3B are external views of a cover according to a first modification;

FIGS. 4A to 4C are explanatory views of a cover according to a second modification;

FIGS. 5A and 5B are external views of a cover according to a third modification; and

FIGS. 6A to 6C are explanatory views of a cover according to a fourth modification.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An object of the present disclosure is to provide a wiring unit that can suppress entry of dew condensation water and the like into a connecting portion between a flexible printed circuit board and a connector.

The present disclosure employs the following means to solve the above problems.

The wiring unit according to the present disclosure includes a flexible printed circuit board, a connector, a holding member, and a cover, in which the flexible printed circuit board has a first surface and a second surface opposite to the first surface, and has a plurality of wirings; the connector has a housing case and a plurality of terminals, the connector is connected to the first surface of the flexible printed circuit board at one end side in a longitudinal direction of the flexible printed circuit board, the plurality of terminals are provided to protrude from an inside of the housing case to an outside and to be respectively connected to the plurality of wirings on the other end side in the longitudinal direction from the housing case; the holding member is provided to hold the flexible printed circuit board on the second surface of the flexible printed circuit board; the cover is provided to sandwich the connector between the cover and the holding member in a thickness direction of the flexible printed circuit board; the holding member has a recess, and the recess is located on the other end side in the longitudinal direction from the plurality of terminals, and is provided to be recessed toward a side opposite to the connector in the thickness direction, and the cover has a pressing portion, and the pressing portion is provided to press and make a part of the flexible printed circuit board enter the recess.

According to the present disclosure, even when dew condensation water or the like flows toward the connecting portion between the FPC and the connector through the FPC, the dew condensation water or the like enters the recess. Therefore, it is possible to suppress the entry of the dew condensation water and the like into the connecting portion.

In a short direction of the flexible printed circuit board, a range where the recess and the pressing portion are provided may be configured to include a range where the plurality of terminals are provided.

This makes it possible to suppress adhesion of the dew condensation water and the like to any of the plurality of terminals.

The pressing portion may be configured to press the part of the flexible printed circuit board against a wall surface of the recess on the one end side in the longitudinal direction.

Thus, the part of the flexible printed circuit board is sandwiched between the wall surface of the recess and the pressing portion, so that it is possible to more reliably suppress the entry of the dew condensation water and the like into the connecting portion between the FPC and the connector.

The pressing portion has a protrusion, and the protrusion may be configured to press the part of the flexible printed circuit board against the wall surface of the recess on the one end side in the longitudinal direction.

This increases a surface pressure peak pressing the flexible printed circuit board by the pressing portion (the protrusion), so that it is possible to more reliably suppress the entry of dew condensation water and the like into the connecting portion between the FPC and the connector.

The cover has a pair of walls, and the pair of walls may be configured to cover both sides of portions protruding from the housing case in the plurality of terminals.

This makes it possible to suppress touching the terminal by some member or the like.

It is also preferable that the wiring unit further includes a hinge, in which the holding member and the cover are integrated with each other via the hinge.

This makes it possible to reduce the number of parts.

It is also preferable that the wiring unit further includes a flexible printed circuit board cover, in which the flexible printed circuit board cover covers the flexible printed circuit board and is integrated with the cover.

This makes it possible to reduce the number of parts.

Note that each of the above configurations can be adopted in combination as much as possible.

As described above, according to the present disclosure, it is possible to suppress the entry of the dew condensation water and the like into the connecting portion between the flexible printed circuit board and the connector.

An embodiment of the present disclosure will be exemplarily described in detail below with reference to the drawings. However, dimensions, materials, shapes, relative arrangements, and the like of components described in the present embodiment do not limit the scope of the present disclosure, unless otherwise specified.

### Embodiment

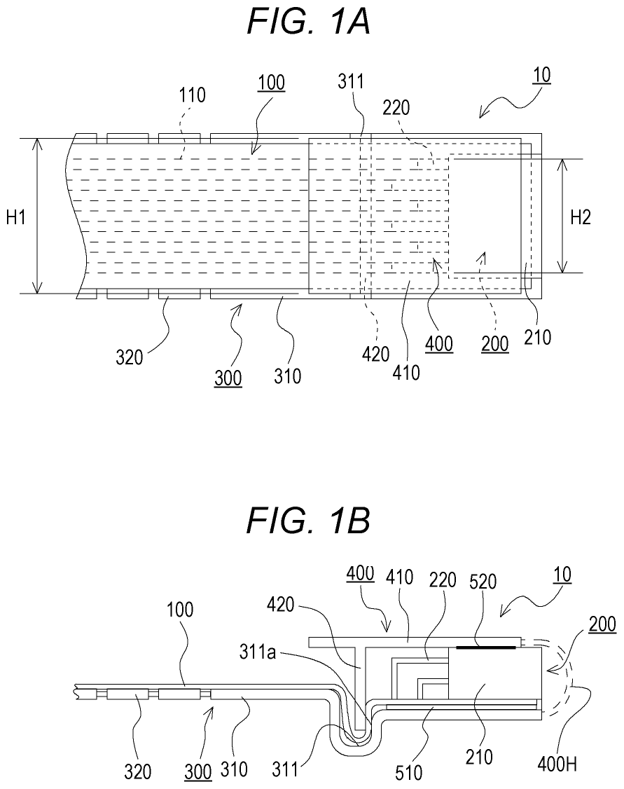

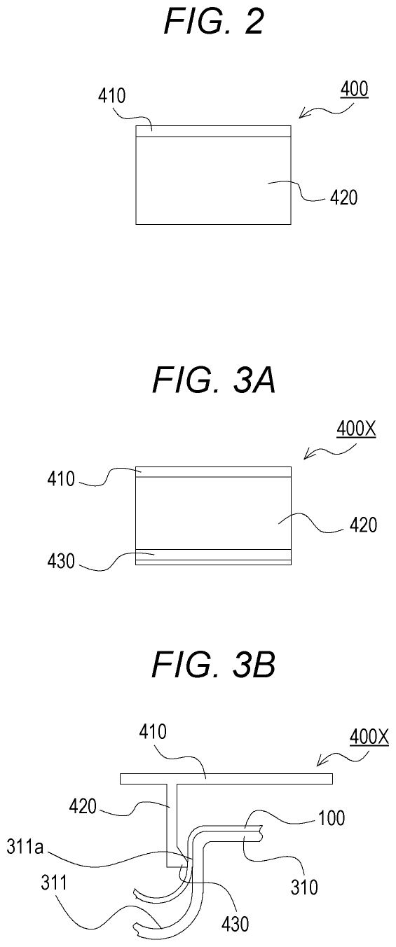

The wiring unit according to the embodiment of the present disclosure will be described with reference to FIGS. 1A, 1B, and 2. FIGS. 1A and 1B are parts of an external view of the wiring unit according to the embodiment of the present disclosure, FIG. 1A is a part of a plan view, and FIG. 1B is a part of a side view. Note that in FIG. 1A, a part of main components is illustrated in perspective and by dotted lines. FIG. 2 is a front view of the cover according to the embodiment of the present disclosure, and corresponds to a view of the cover in FIG. 1B viewed from the right side in the figure.

### <Schematic Configuration of Wiring Unit>

A wiring unit 10 according to the present embodiment includes a flexible printed circuit board (hereinafter referred to as “FPC 100”), a connector 200 connected to the FPC 100, and a holding member 300 that holds the FPC 100 to which the connector 200 is connected.

In the present embodiment, a left-right direction in the plan view of FIG. 1A may be referred to as a longitudinal direction or a length direction of the FPC 100, and an up-down direction in the plan view of FIG. 1A may be referred to as a short direction or a width direction of the FPC 100. Further, a vertical direction in the side view of FIG. 1B may be referred to as a thickness direction of the FPC 100.

Since the FPC 100 itself is a known technology, a detailed explanation thereof will be omitted, and a structure thereof will be simply explained. The FPC 100 includes a base film (not illustrated), wiring 110 made of copper foil or the like provided on a surface of the base film, and a cover film that protects the wiring 110. The present disclosure is also applicable to a single-sided FPC in which the wiring and the cover film are provided on only one side of the base film, a double-sided FPC in which the wiring and the cover film are provided on both sides of the base film, and an FPC with a more multilayer structure.

In the present embodiment, a surface of the FPC 100 to which the connector 200 is connected may be referred to as a first surface, and the surface opposite to the first surface in the thickness direction of the FPC 100 may be referred to as a second surface.

The connector 200 includes a housing case 210 and a plurality of terminals 220. The plurality of terminals 220 are provided to protrude from the inside of the housing case 210 to the outside. Further, the plurality of terminals 220 are connected to the wiring 110 provided in the FPC 100. More specifically, an opening is provided in a part of the cover film in the FPC 100, and a tip of the terminal 220 is connected to the wiring 110 exposed in the opening by soldering. Note that it is desirable that connection between the FPC 100 and the connector 200 is not limited to connection between the terminal 220 and the wiring 110, but is fixed separately by, for example, bonding the housing case 210 and the FPC 100 with an adhesive or a double-sided tape.

In the present embodiment, the connector 200 is connected to the first surface (an upper surface) of the FPC 100 on a right end side (one end side) in the longitudinal direction of the FPC 100.

The holding member 300 includes a first holding member 310 and a second holding member 320. In the present embodiment, the holding member 300 is configured to hold the FPC 100 on the second surface (a lower surface) of the FPC 100 from the right end side (one end side) to the left end side (other end side) in the longitudinal direction of the FPC 100.

The first holding member 310 holds a portion of the FPC 100 near where the housing case 210 is connected. A plurality of the second holding members 320 are connected to each other in a state where each of them is allowed to move to some extent in the longitudinal direction of the FPC 100.

The FPC 100 and the first holding member 310 may be fixed by directly bonding them together using an adhesive, a double-sided tape, or the like. Alternatively, the FPC 100 and the first holding member 310 may be indirectly fixed by fixing the connector 200 and the first holding member 310 by using a fixing tool such as a screw member or by adopting a snap-fit structure. Note that FIG. 1B illustrates, as an example, a configuration in which the FPC 100 and the first holding member 310 are bonded with a double-sided tape 510.

Regarding a structure for fixing the second holding member 320 and the FPC 100, various structures can be employed, such as providing the second holding member 320 with locking claws that lock both sides in the width direction of the FPC 100. As described above, since the plurality of second holding members 320 are connected to each other in the state where each of them is allowed to move to some extent in the longitudinal direction of the FPC 100, the holding member 300 can also be suitably applied to devices that expand and contract in the longitudinal direction of the FPC 100 and devices with large dimensional tolerances. Further, since the FPC 100 has flexibility, even when the second holding member 320 moves a little, there is no problem in terms of quality.

Then, the wiring unit 10 according to the present embodiment includes a cover 400. The cover 400 is provided to sandwich the connector 200 between the cover 400 and the holding member 300. Specifically, the connector 200 is sandwiched between the cover 400 and the holding member 300 in the vertical direction (the thickness direction of the FPC 100) in the side view of FIG. 1B.

The cover 400 includes a top plate portion 410 and a pressing portion 420. Further, the cover 400 can be fixed to the FPC 100 and the holding member 300 by, for example, bonding the top plate portion 410 and the connector 200 (the housing case 210) with an adhesive or a double-sided tape. In an illustrated example, a configuration is illustrated in which the cover 400 and the housing case 210 of the connector 200 are fixed with a double-sided tape 520. However, the cover 400 and the connector 200 may be fixed using, for example, a fixing tool such as a screw member. Further, the cover 400 can also be fixed to the first holding member 310 by using a fixing tool such as a screw member or by adopting a snap-fit structure.

Note that in the present embodiment, a case is illustrated in which the holding member 300 and the cover 400 are constituted by separate members (separate bodies). However, the holding member 300 and the cover 400 can also be integrated into one component. In this case, for example, as illustrated by dotted lines in FIG. 1B, a portion corresponding to the holding member 300 and a portion corresponding to the cover 400 is configured to be connected by a flexible hinge 400H. Thus, the holding member and the cover are integrally formed via the hinge 400H. When this configuration is adopted, after the FPC 100 and the connector 200 are attached to the portion corresponding to the holding member 300, the portion corresponding to the cover 400 may be fixed by bending the hinge 400H. By adopting the above configuration, the number of parts can be reduced.

<Structure that Suppresses Entry of Dew Condensation Water and the Like into Connecting Portion Between Connector and FPC>

A recess 311 is provided in the first holding member 310. The recess 311 is configured to be recessed toward a side opposite to the cover 400 via the connector 200 at a position opposite to the housing case 210 via portions protruding from the housing case 210 in the plurality of terminals 220.

The recess 311 is located on the other end side (left end side in FIG. 1B) of the FPC 100 from the plurality of terminals 220 of the connector 200 in the longitudinal direction of the FPC 100. Further, the recess 311 is provided to be recessed toward a side (lower side in FIG. 1B) opposite to the connector 200 in the thickness direction of the FPC 100.

Further, as described above, the cover 400 is provided with the pressing portion 420. The pressing portion 420 is configured to press and make a part of the FPC 100 enter the recess 311. That is, by attaching the cover 400 to the housing case 210 or the first holding member 310, the pressing portion 420 presses the part of the FPC 100. As a result, a portion of the FPC 100 pressed curves and enters the recess 311.

In the present embodiment, the pressing portion 420 is provided to press the part of the FPC 100 located above the recess 311 in a direction (direction from top to bottom in FIG. 1B) from the first surface to the second surface of the FPC 100.

Here, a range H1 where the pressing portion 420 is provided in the short direction of the FPC 100 is configured to include a range H2 where the plurality of terminals 220 of the connector 200 are provided in the short direction of the FPC 100. Note that a range where the recess 311 is provided in the short direction of the FPC 100 also includes the range H1 where the pressing portion 420 is provided. Therefore, in the short direction of the FPC 100, it can be said that the range where the recess 311 and the pressing portion 420 are provided includes the range H2 where the plurality of terminals 220 are provided. Note that in the present embodiment, although the recess 311 is provided over the entire width direction of the first holding member 310, it is not necessarily provided over the entire width direction. Further, although the pressing portion 420 is provided over the entire width direction of the cover 400, it is not necessarily provided over the entire width direction.

### <Advantages of Wiring Unit According to the Present Embodiment>

With the wiring unit 10 according to the present embodiment, a configuration is adopted in which the first holding member 310 is provided with the recess 311, and the cover 400 is provided with the pressing portion 420 that presses and makes a part of the FPC 100 enter the recess 311. Thus, even when the dew condensation water or the like flows toward the connecting portion (hereinafter may be referred to as the connecting portion) between the FPC 100 and the connector 200 through the FPC 100, the dew condensation water or the like enters the recess 311, so that it is possible to suppress the entry of the dew condensation water and the like into the connecting portion. Therefore, short circuits and deterioration of the terminals 220 can be suppressed.

Further, in the present embodiment, in the short direction of the FPC 100, the range where the recess 311 and the pressing portion 420 are provided is configured to include the range H2 where the plurality of terminals 220 are provided. This makes it possible to suppress adhesion of the dew condensation water and the like to any of the plurality of terminals 220.

Here, the pressing portion 420 is desirably configured to press a part of the FPC 100 against the wall surface 311a of the recess 311 on a side where the connector 200 is provided (see FIG. 1B). With such a configuration, a part of the FPC 100 is sandwiched between the wall surface 311a of the recess 311 and the pressing portion 420, so that it is possible to more reliably suppress the entry of the dew condensation water and the like into the connecting portion. Note that the side where the connector 200 is provided corresponds to the one end side in the longitudinal direction of the FPC 100.

Modifications of the cover 400 will be described below.

### (First Modification)

FIGS. 3A and 3B are external views of a cover 400X according to a first modification, FIG. 3A is a front view of the cover 400X, and FIG. 3B is a side view of the cover 400X. FIG. 3B also illustrates a portion near the recess 311 of the FPC 100 and of the first holding member 310.

The cover 400X according to the first modification also includes the top plate portion 410 and the pressing portion 420, similarly to the cover 400 illustrated in the above embodiment. Then, in the cover 400X, the pressing portion 420 is provided with a protrusion 430 that presses a part of the FPC 100 against the wall surface 311a of the recess 311 on the side where the connector 200 is provided.

The cover 400X configured as described above can also obtain the same effects as when the cover 400 is used. Further, when the cover 400X is used, the surface pressure peak pressing the FPC 100 by the pressing portion 420 (protrusion 430) increases, so that it is possible to more reliably suppress the entry of the dew condensation water and the like into the connecting portion. That is, compared to a case where a part of the FPC 100 is pressed by a plane portion of the pressing portion 420 as illustrated in FIG. 1B, pressing a part of the FPC 100 with the protrusion 430 can more locally pressing the FPC 100. Thus, the surface pressure peak can be increased.

### (Second Modification)

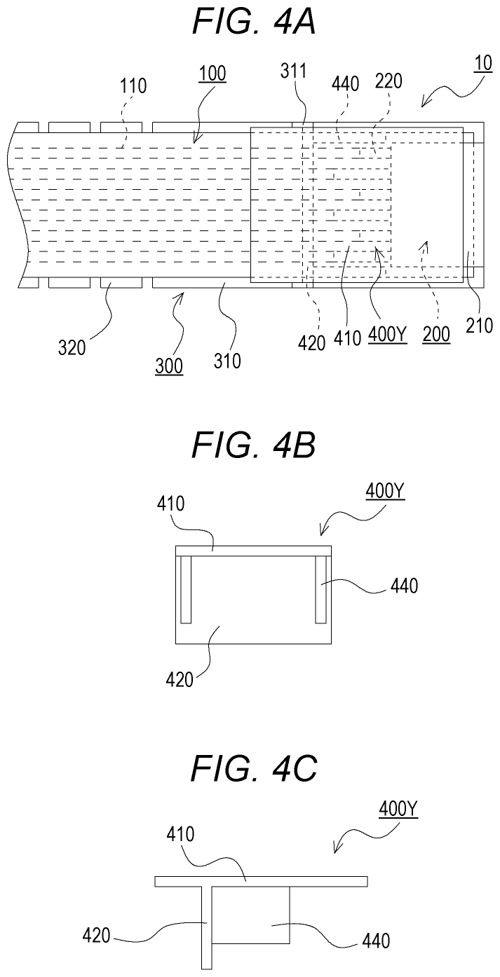

FIGS. 4A to 4C are external views of a cover 400Y according to a second modification, FIG. 4A is a partial plan view of the wiring unit 10 including the cover 400Y, and FIG. 4B is a front view of the cover 400Y, and FIG. 4C is a side view of the cover 400Y. Note that in FIG. 4A, a part of main components is illustrated in perspective and by dotted lines.

The cover 400Y according to the second modification also includes the top plate portion 410 and the pressing portion 420, similarly to the cover 400 illustrated in the above embodiment. Then, a configuration is adopted in which the cover 400Y has a pair of walls 440 that cover both sides of portions of the plurality of terminals 220 that protrude from the housing case 210.

The cover 400Y configured as described above can also obtain the same effects as when the cover 400 is used. Further, when the cover 400Y is used, it is possible to suppress touching of the terminals 220 by some member or the like. That is, it is possible to suppress touching of the terminals 220 by some member constituting a device to which the wiring unit 10 is applied, or touching of the terminals 220 by some object such as dust when the wiring unit 10 is used for outdoor equipment.

### (Third Modification)

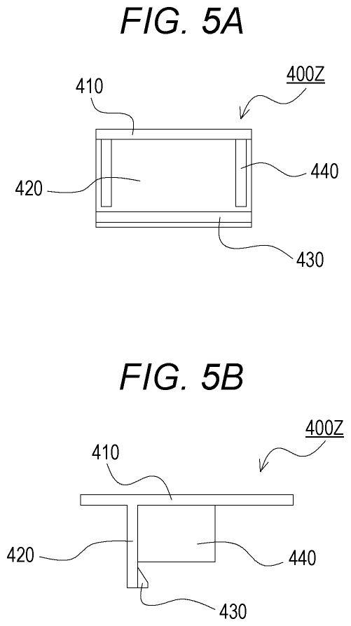

FIGS. 5A and 5B are external views of a cover 400Z according to a third modification, FIG. 5A is a front view of the cover 400Z, and FIG. 5B is a side view of the cover 400Z.

The cover 400Z according to the third modification also includes the top plate portion 410 and the pressing portion 420, similarly to the cover 400 illustrated in the above embodiment. Then, a configuration is adopted in which the cover 400Z is provided with the protrusion 430 as in the first modification, and has the pair of walls 440 as in the second modification. The cover 400Z configured as described above can also obtain the same effects as when the cover 400 is used. Further, when the cover 400Z is used, effects of the first modification and the second modification can also be obtained.

### (Fourth Modification)

In a structure in which the FPC is held by the holding member, it is also preferable to provide a flexible printed circuit board cover to protect the FPC. For example, a cover for protecting the connector 200 described above can also be configured to be integrated with a cover for protecting the flexible printed circuit board.

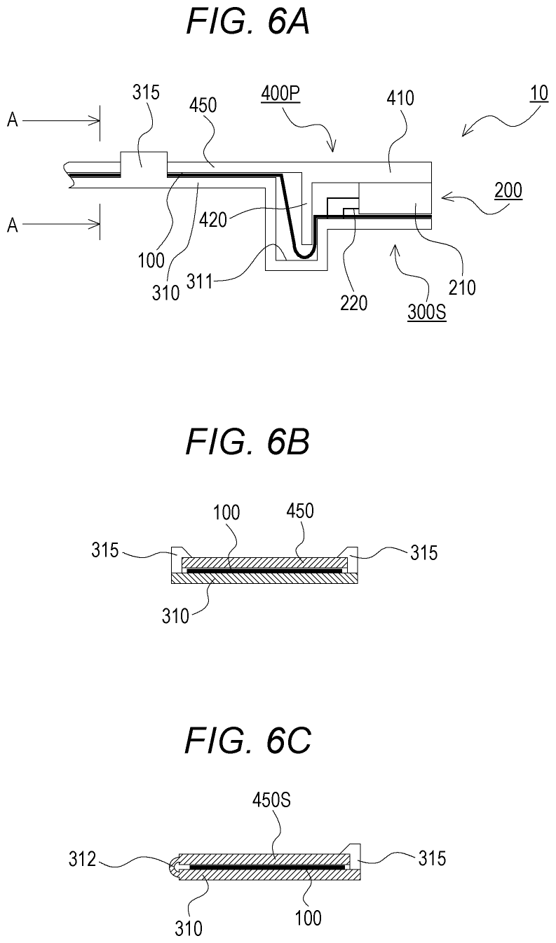

FIGS. 6A to 6C illustrate an example of such a configuration. FIG. 6A is a schematic diagram of a part of a side view of the wiring unit in which a cover 400P according to a fourth modification is adopted. Note that the same components as those illustrated in the embodiment are denoted by the same reference numerals, and description thereof will be omitted as appropriate. The cover 400P according to the fourth modification includes the top plate portion 410 that covers the connector 200 and the pressing portion 420, similarly to the cover 400 illustrated in the above embodiment. Then, in the cover 400P, an FPC cover 450 that covers the FPC 100 is provided integrally with the top plate portion 410 and the pressing portion 420. Thus, the number of parts can be reduced.

Note that a structure for fixing the FPC cover 450 is not particularly limited, and a fixing tool such as a screw member may be used. Examples illustrated in FIGS. 6A to 6C illustrate a structure using a snap fit 315 as an example of the fixing tool. That is, the FPC cover 450 can be fixed by the snap fit 315 provided on the holding member 300S. In this case, as illustrated in FIG. 6B, a configuration can be adopted in which a pair of snap fits 315 are provided on both sides of the first holding member 310.

Further, a configuration can also be adopted in which the holding member 300S and the cover 400P are integrated. In this case, for example, as illustrated in FIG. 6C, the holding member 300S (the first holding member 310) and an FPC cover 450S are integrated via a hinge 312. In this case, for example, a snap fit 315 is provided on one side (a side opposite to the hinge 312) of the first holding member 310. Note that FIGS. 6B and 6C correspond to A-A cross-sectional views in FIG. 6A. Note that a configuration illustrated in any of the first to third modifications can also be applied to a configuration of the cover 400P according to the fourth modification.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A wiring unit comprising:
a flexible printed circuit board;
a connector;
a holding member; and
a cover, wherein
the flexible printed circuit board has a first surface and a second surface opposite to the first surface, and has a plurality of wirings,
the connector has a housing case and a plurality of terminals,
the connector is connected to the first surface of the flexible printed circuit board at one end side in a longitudinal direction of the flexible printed circuit board,
the plurality of terminals are provided to protrude from an inside of the housing case to an outside and to be respectively connected to the plurality of wirings on the other end side in the longitudinal direction from the housing case,
the holding member is provided to hold the flexible printed circuit board on the second surface of the flexible printed circuit board,
the cover is provided to sandwich the connector between the cover and the holding member in a thickness direction of the flexible printed circuit board,
the holding member has a recess, and the recess is located on the other end side in the longitudinal direction from the plurality of terminals, and is provided to be recessed toward a side opposite to the connector in the thickness direction, and
the cover has a pressing portion, and the pressing portion is provided to press and make a part of the flexible printed circuit board enter the recess.

2. The wiring unit according to claim 1, wherein in a short direction of the flexible printed circuit board, a range where the recess and the pressing portion are provided is configured to include a range where the plurality of terminals are provided.

3. The wiring unit according to claim 1, wherein the pressing portion is configured to press the part of the flexible printed circuit board against a wall surface of the recess on the one end side in the longitudinal direction.

4. The wiring unit according to claim 3, wherein
the pressing portion has a protrusion, and
the protrusion is configured to press the part of the flexible printed circuit board against the wall surface of the recess on the one end side in the longitudinal direction.

5. The wiring unit according to claim 1, wherein
the cover has a pair of walls, and
the pair of walls are configured to cover both sides of portions protruding from the housing case in the plurality of terminals.

6. The wiring unit according to claim 1, further comprising a hinge, wherein
the holding member and the cover are integrated with each other via the hinge.

7. The wiring unit according to claim 1, further comprising a flexible printed circuit board cover, wherein
the flexible printed circuit board cover covers the flexible printed circuit board and is integrated with the cover.
